(19) United States
(12) Patent Application Publication
(10) Pub. No.: US 2016/0161531 A1
(43) Pub. Date: Jun. 9, 2016

(54) MAGNETO-RESISTIVE SENSOR DEVICE AND MAGNETIC BIAS REGULATOR CIRCUIT, ALONG WITH SYSTEMS AND METHODS INCORPORATING SAME

(71) Applicant: Server Technology, Inc., Reno, NV (US)

(72) Inventor: William Harold Avery, Reno, NV (US)

(21) Appl. No.: 14/959,207

(22) Filed: Dec. 4, 2015

Related U.S. Application Data
(60) Provisional application No. 62/087,424, filed on Dec. 4, 2014.

(51) Int. Cl. G01R 15/20; H02J 3/00; G01R 33/09

(52) U.S. Cl. CPC G01R 15/205; G01R 33/098; H02J 3/00

(57) ABSTRACT

Various embodiments of the present disclosure are related to systems, devices, and methods for current sensing. In one example, a current sensing circuit includes a magneto-resistive sensor device proximate to a current carrying conductor and configured to output a voltage representative of a current carried by the proximate current carrying conductor and a first sensor feedback loop responsive to an alternating magnetic field generated by the current carried by the current carrying conductor. The first sensor feedback loop is configured to supply a bias current to the magneto-resistive sensor device and substantially cancel the alternating magnetic field generated by the current carried by the current carrying conductor.

### CROSS-REFERENCE TO RELATED APPLICATION(S)

This application claims priority to U.S. Provisional Application No. 62/087,424, filed Dec. 4, 2014, the contents of which are expressly incorporated by reference herein.

This application is related to U.S. Pat. Nos. 7,043,543, 7,777,365 and 8,305,737, the contents of which are expressly incorporated by reference herein.

### BACKGROUND

A Magnetic Tunnel Junction (MTJ), a form of magneto-resistive device, can be used to measure magnetic field strength. As the magnetic field varies, the internal resistance of the sensor varies. Placing an MTJ device in close proximity with a current carrying conductor allows the MTJ to convert the associated magnetic field, due to current flow, to a resistance which can be used to produce a voltage representative of this current. The variation in resistance as a function of the magnetic field strength at the MTJ is approximately linear over a small range, i.e., the quasi-linear response region, but becomes progressively non-linear for large magnetic fields.

The quasi-linear region of the variation in resistance as a function of the magnetic field strength at the MTJ sensor device occurs at non-zero field strength. The resistance vs. magnetic field response curve of a typical MTJ sensor has a quasi-linear region where a change in the applied magnetic field has a corresponding approximately linear change in the sensor's output resistance. Applied magnetic fields outside of this range have a corresponding non-linear change in the sensor's output resistance. Accordingly, a fixed, internal magnetic bias is typically used in an attempt to ensure that the MTJ sensor device produces a linear variation in resistance as a function of an externally applied alternating magnetic field associated with alternating currents. Unfortunately, measuring large currents can drive the MTJ sensor's output beyond its quasi-linear range, compressing the peaks of an AC waveform. This compression of the AC peaks may lead to accuracy errors.

Accordingly, a need exists for technology that overcomes the problem demonstrated above, as well as one that provides additional benefits. The examples provided herein are of some prior or related systems and their associated limitations are intended to be illustrative and not exclusive. Other limitations of existing or prior systems will become apparent to those of skill in the art upon reading the following Detailed Description.

### SUMMARY

The present disclosure relates to systems, methods, and apparatus for sensing electrical current with a magneto-resistive sensor device. In one implementation, a current sensing circuit includes a magneto-resistive sensor device proximate to a current carrying conductor and configured to output a voltage representative of a current carried by the proximate current carrying conductor; and a first sensor feedback loop responsive to an alternating magnetic field generated by the current carried by the current carrying conductor, the first sensor feedback loop being configured to supply a bias current to the magneto-resistive sensor device, and substantially cancel the alternating magnetic field generated by the current carried by the current carrying conductor.

In some examples, the current sensing circuit also includes a second sensor feedback loop configured to adjust an average level of the bias current. In some examples, the first sensor feedback loop includes an operational amplifier in electrical communication with the magneto-resistive sensor device. In some examples, the current sensing circuit also includes an analog-to-digital converter configured to sample the output of the magneto-resistive sensor device. In some examples, a center level of the bias current is based at least in part on a full scale input level of the analog-to-digital convertor. In some examples, the current carrying conductor is a power output component of an electronic power distribution plugstrip. In some examples, the current carrying conductor is a power input component of an electronic power distribution plugstrip.

In one implementation, a current sensing system includes a current carrying conductor; a magneto-resistive sensor device proximate to the current carrying conductor and configured to: determine a magnetic field strength in the vicinity of the magneto-resistive sensor device, wherein the magnetic field strength comprises an external alternating magnetic field component occurring as a result of a current carried by the current carrying conductor and an internal magnetic field component occurring as a result of an internal magnetic bias of the magneto-resistive sensor device; and convert the magnetic field strength to a voltage representative of the current carried by the current carrying conductor; and a magnetic bias regulator configured to: detect resistance information associated with the magneto-resistive sensor device; and modify the internal magnetic bias of the magneto-resistive sensor device based at least in part on the resistance information.

In some examples, current sensing system also includes an analog-to-digital converter configured to sample the voltage representative of the current in the current carrying conductor. In some examples, the current carrying conductor is a power output component of an electronic power distribution plugstrip. In some examples, the current carrying conductor is a power input component of an electronic power distribution plugstrip. In some examples, current sensing system also includes a current-related information display in current determining communication with the magneto-resistive sensor device.

In one implementation, a method for sensing current includes monitoring a magneto-resistive sensor device for sensor feedback; and generating a bias control signal based on the sensor feedback, wherein the bias control signal substantially cancels an externally applied alternating magnetic field from a current carrying conductor.

In one implementation, an electrical power distribution plugstrip connectable to one or more electrical loads in a vertical electrical equipment rack, the electrical power distribution plugstrip includes A. a vertical strip enclosure having a thickness and a length longer than a width of the enclosure; B. a power input penetrating said vertical strip enclosure; C. a plurality of power outputs disposed along a face of said length of the strip enclosure, each among the plurality of power outputs being connectable to a corresponding one of said one or more electrical loads; D. a plurality of power control relays disposed in said vertical strip enclosure, each among said plurality of power control relays being connected to said power input and one or more of said plurality of power outputs; E. a current-related information display disposed on said vertical strip enclosure in current-related information-determining communication with at least one among said power input and said plurality of power outputs, wherein the current-related information display is in current determining communication with all among the plurality of power outputs through at least one current sensing device, the current sensing device comprising a magneto-resistive sensor device and a magnetic bias regulator; and F. a current-related information reporting system associated with said vertical strip enclosure and being (i) in current-related information-determining communication with at least one among said power input and said plurality of power outputs, and (ii) connectable in current-related information transfer communication with a separate communications network distal from the electrical power distribution plugstrip.

It is to be understood that both the foregoing summary and the following detailed description are for purposes of example and explanation and do not necessarily limit the present disclosure. The accompanying drawings, which are incorporated in and constitute a part of the specification, illustrate subject matter of the disclosure. Together, the descriptions and the drawings serve to explain the principles of the disclosure.

### BRIEF DESCRIPTION OF THE DRAWINGS

FIG. 1 is a block diagram illustrating an example magnetic bias regulator configured to regulate internal magnetic bias of a magneto-resistive sensor device, according to an embodiment;

FIG. 2 is a schematic electrical diagram showing an example magnetic bias regulator configured to regulate internal magnetic bias of a magneto-resistive sensor device, according to an embodiment;

FIG. 3 is an example response curve illustrating output resistance of a magneto-resistive sensor device as a function of an external alternating magnetic field, according to an embodiment;

FIG. 4 is an example electrical power distribution plugstrip including one or more magneto-resistive sensor devices, according to an embodiment; and

FIG. 5 is a schematic electrical diagram showing an example of a magneto-resistive sensing system, according to an embodiment.

Sizes of various depicted elements are not necessarily drawn to scale and these various elements may be arbitrarily enlarged to improve legibility. As is conventional in the field of electrical circuit representation, sizes of electrical components are not drawn to scale, and various components can be enlarged or reduced to improve drawing legibility. Component details have been abstracted in the Figures to exclude details such as position of components and certain precise connections between such components when such details are unnecessary to the disclosure.

### DETAILED DESCRIPTION

The following description and drawings are illustrative and are not to be construed as limiting. Numerous specific details are described to provide a thorough understanding of the disclosure. However, in certain instances, well-known or conventional details are not described in order to avoid obscuring the description. References to one or an embodiment in the present disclosure can be, but not necessarily are, references to the same embodiment; and, such references mean at least one of the embodiments.

Reference in this specification to “one embodiment” or “an embodiment” means that a particular feature, structure, or characteristic described in connection with the embodiment is included in at least one embodiment of the disclosure. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but no other embodiments.

The terms used in this specification generally have their ordinary meanings in the art, within the context of the disclosure, and in the specific context where each term is used. Certain terms that are used to describe the disclosure are discussed below, or elsewhere in the specification, to provide additional guidance to the practitioner regarding the description of the disclosure. For convenience, certain terms may be highlighted, for example, using italics and/or quotation marks. The use of highlighting has no influence on the scope and meaning of a term; the scope and meaning of a term is the same, in the same context, whether or not it is highlighted. It will be appreciated that same thing can be said in more than one way.

Consequently, alternative language and synonyms may be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification, including examples of any terms discussed herein, is illustrative only, and is not intended to further limit the scope and meaning of the disclosure or of any exemplified term. Likewise, the disclosure is not limited to various embodiments given in this specification.

Without intent to further limit the scope of the disclosure, examples of instruments, apparatus, methods and their related results according to the embodiments of the present technology are given below. Note that titles or subtitles may be used in the examples for convenience of a reader, which in no way should limit the scope of the disclosure. Unless otherwise defined, all technical and scientific terms used herein have the same meaning as commonly understood by one of ordinary skill in the art to which this disclosure pertains. In the case of conflict, the present document, including definitions, will control.

Various examples of the present technology will now be described. The following description provides certain specific details for a thorough understanding and enabling description of these examples. One skilled in the relevant technology will understand, however, that the examples may be practiced without many of these details. Likewise, one skilled in the relevant technology will also understand that the examples may include many other obvious features not described in detail herein. Additionally, some well-known structures or functions may not be shown or described in detail below, to avoid unnecessarily obscuring the relevant descriptions of the various examples.

The terminology used below is to be interpreted in its broadest reasonable manner, even though it is being used in conjunction with a detailed description of certain specific examples. Indeed, certain terms may even be emphasized below; however, any terminology intended to be interpreted in any restricted manner will be overtly and specifically defined as such in this Detailed Description section.

Embodiments of the present disclosure describe techniques for regulating and/or otherwise maintaining a quasi-linear relationship between the magnetic field from a current carrying conductor in close proximity to a magneto-resistive sensor device (e.g., an MTJ sensor) and the output from a current sensing circuit. More specifically, the techniques provide a closed-loop feedback circuit (e.g., a magnetic bias regulator) that monitors the magneto-resistive sensor device's output (e.g., sensing resistance) and provides a feedback signal which responsively controls and/or otherwise varies a bias current to keep a combined or overall magnetic field at the magneto-resistive device constant. As described above, keeping the combined or overall magnetic field at the magneto-resistive device constant allows the magneto-resistive device to operate at a specific point along the non-linear curve within the quasi-linear region of the sensor's response curve. The relationship between the bias current and the magnetic field it produces (i.e., the internal magnetic field) is approximately linear. Because the bias current can be used to cancel the effect of the external field, an approximately linear relationship between the current flowing in the conductor and the current flowing in the bias winding of the magneto-resistive sensor device is ensured.

The technology described herein overcomes the nonlinearity limitations discussed above (e.g., the nonlinear output resistance attributes of MTJ sensor devices) by maintaining a relatively constant magnetic field at the magneto-resistive sensor device. As the external alternating magnetic field varies, the value of the sensing resistance is detected and used to generate variations in the internal magnetic field produced by the bias current so that the combined fields do not change. The variations in the bias current are then used to generate a signal which has a quasi-linear relationship to an external current in a current carrying device (or conductor). In some embodiments, this voltage signal can be AC coupled and the resultant AC output voltage measured to find the current in the conductor.

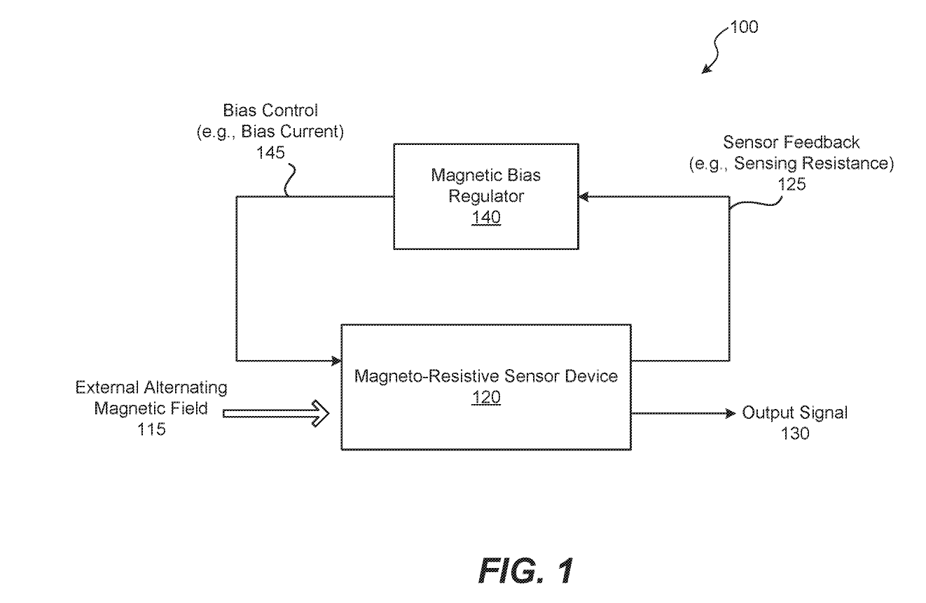

FIG. 1 is a block diagram illustrating an example of a magneto-resistive sensing system 100, according to an embodiment. The system 100 includes a magnetic bias regulator 140 (configured to regulate internal magnetic bias of a magneto-resistive sensor device 120. In some embodiments, the magneto-resistive sensor device 120 may be a discrete MTJ sensor, such as those designed and developed by Crocus Technology. Although shown as discrete components, functionality of the magneto-resistive sensor device 120 and/or the magnetic bias regulator 140 can be, in whole or in part, packaged in one or more integrated circuit(s).

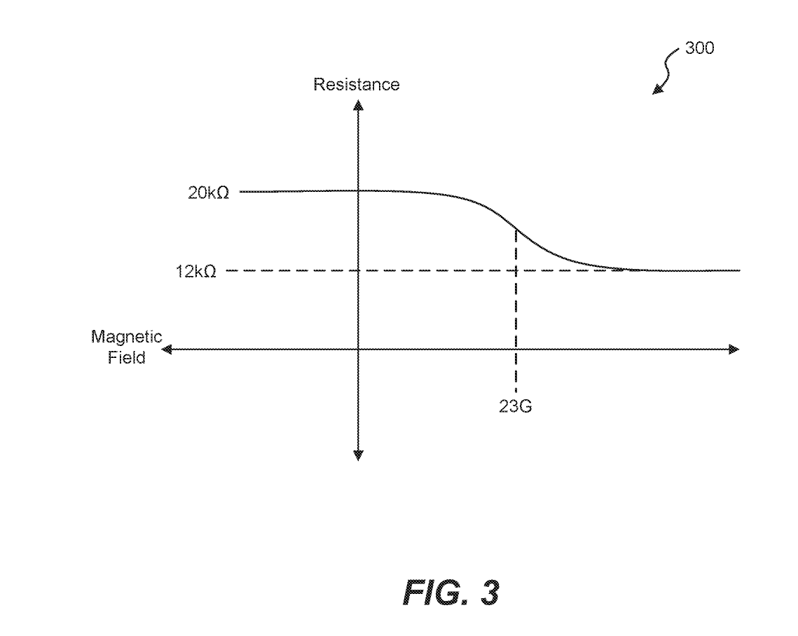

The magneto-resistive sensor device 120 is configured to determine and/or otherwise measure the strength of a proximate external alternating magnetic field 115 that is associated with a proximate AC current carrying conductor (not shown). As discussed above, for alternating currents, the variation in output resistance of the magneto-resistive sensor device 120 as a function of the total magnetic field strength at the sensor device 120 occurs at non zero field strength (see, for example, FIG. 3). Accordingly, bias control (e.g., bias current) 145 is used to produce a quasi-linear variation in output voltage of the magneto-resistive sensor device 120 as a function of the external alternating magnetic field 115.

The magnetic bias regulator 140 interacts with and is otherwise communicatively coupled with the magneto-resistive sensor device 120 facilitating closed-loop resistive sensing feedback. The magnetic bias regulator 140 receives sensor feedback (e.g., sensing resistance) 125 and uses the feedback to dynamically control the variable bias current 145. As discussed above, by varying the bias current 145, the magnetic bias regulator 140 is able to keep the combined or overall magnetic field at the magneto-resistive device relatively constant even with large external alternating magnetic fields corresponding to large external alternating currents of the current carrying conductor. Maintaining the overall magnetic field at the magneto-resistive sensor device 120 relatively constant maintains a quasi-linear relationship between the external magnetic field and the output signal 130.

In one embodiment, the magnetic bias regulator 140 regulates the internal magnetic field strength of the magneto-resistive sensor device 120 by facilitating closed-loop sensing resistance feedback. The magnetic bias regulator 140 can regulate the magnetic field strength of the magneto-resistive sensor device 120 by continuously and/or periodically calculating and/or otherwise determining bias control signals 145 which can be, for example, a bias current that is fed back to the magneto-resistive sensor device 120 in order to overcome and/or otherwise counteract the nonlinear output resistance attributes of an MTJ sensor device as a function of an external magnetic field. An example response curve illustrating output resistance of an MTJ sensor device as a function of an external magnetic field is shown and discussed in greater detail with reference to FIG. 3.

The technology described herein overcomes the nonlinear output resistance attributes of magneto-resistive sensor devices by keeping the combined magnetic field at the sensor device substantially constant. That is, as the external magnetic field 115 varies, the internal magnetic field produced by the bias current 145 is varied to keep the combined or overall magnetic field at the magneto-resistive sensor device 120 substantially constant. As described herein, a value of the sensing resistance 125 at the magneto-resistive sensor device 120 is detected by a magnetic bias regulator 140 and used to generate and/or otherwise control a feedback bias current 145 input into the magneto-resistive sensor device 120. The variations in the internal magnetic field produced by the bias current 145 is then used to generate an output signal 130 (e.g., a differential output) which has a quasi-linear relation to the current. In some embodiments, this output signal 130 (e.g., the differential output signal) is AC coupled and the resultant AC output voltage is measured to find the current in the current carrying conductor (not shown).

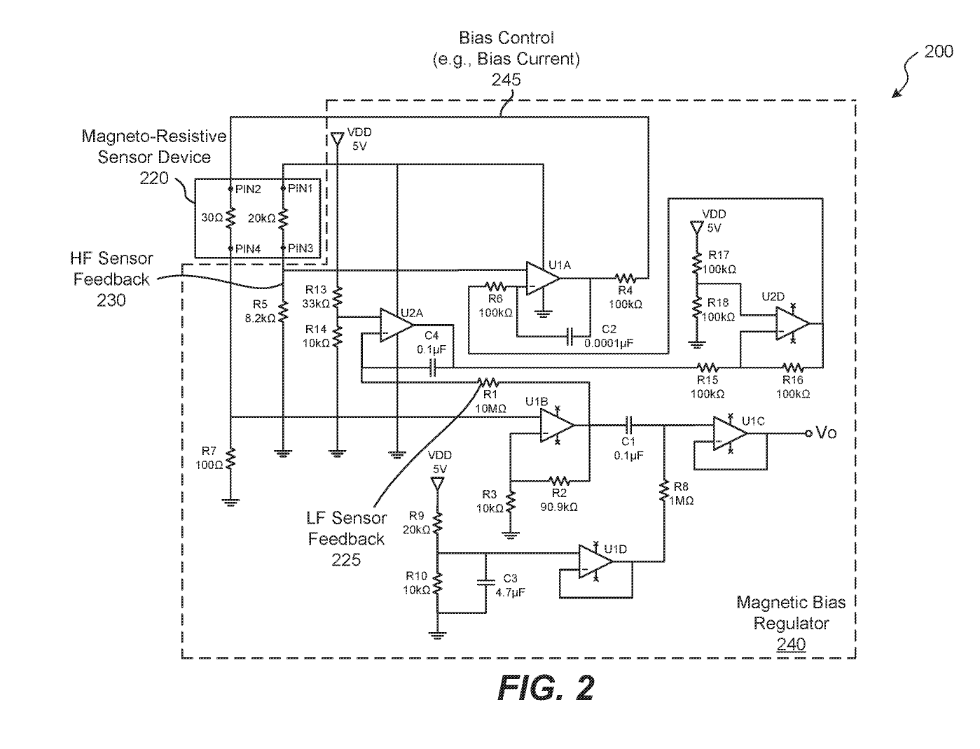

FIG. 2 is a schematic electrical diagram showing an example of a magneto-resistive sensing system 200, according to an embodiment. The system 200 includes a magnetic bias regulator 240 configured to regulate internal magnetic bias of a magneto-resistive sensor device 220, according to an embodiment.

The technology described herein overcomes the nonlinearity limitations discussed above (e.g., the nonlinear output resistance attributes of MTJ sensor devices) by keeping the magnetic field at the magneto-resistive sensor device 220 constant. The magnetic field is kept constant by varying an internal magnetic field so that the field at the magneto-resistive sensor device 220 remains constant.

In some embodiments, the bias point of the magneto-resistive sensor device 220 is determined by including a low frequency (LF) sensor feedback loop 225 with very low bandwidth, for example, less than 1 Hz, that “servos” a bias control 245 (e.g., bias current) to, for example, 12 mA. This bias current is selected to position the fixed operating point of the magneto-resistive sensor device 220 within the quasi-linear region of the sensor's output resistance curve under the condition of a zero external magnetic field. A high frequency (HF) sensor feedback loop 230 with a high gain at 60 Hz varies the AC component of the bias control 245 to cancel the externally applied magnetic field from the current carrying conductor. In this manner, the magneto-resistive sensor device 220 may operate at various bias points on the curve shown in FIG. 3, so long as the bias point remains constant. Variations in the resistance of the magneto-resistive sensor device 220 due to temperature, or variations in resistance due to product variation which would cause non-linearity errors in a typical sensing circuit are mitigated by the feedback loops 225 and 230.

The magnetic bias regulator 240 shown in FIG. 2 represents a unipolar embodiment. It is appreciated that a bipolar bias regulator circuit could also be used to improve the signal to noise ratio of the system 200 by increasing the dynamic range. Other magnetic bias regulator circuit embodiments are also possible. In some embodiments, the system 200 of FIG. 2 utilizes various operational amplifiers (op-amps), e.g., U1A, U1B, U1C and U1D and U2A, and U2D. One or more of these op amps can be, for example, op amps provided by Microchip Technology Inc. of Chandler, Ariz., part no. MCP6024-I/P. Alternative designs and/or op amp chips are also possible. For example, in some embodiments some or all of the functionality of the magnetic bias regulator 240 and/or magneto-resistive sensor device 220 shown in FIG. 2 can be, in whole or in part, packaged in one or more integrated circuit(s).

FIG. 3 is an example response curve 300 illustrating output resistance of an magneto-resistive sensor device (e.g., an MTJ sensor) as a function of an external alternating magnetic field, according to an embodiment. It is understood that response curves correspond to particular products and that actual values vary with, among other factors, the internal dimensions of the magneto-resistive sensor device.

As illustrated in the example of FIG. 3, the output resistance is just over 20 kΩ with no magnetic field (e.g., zero Gauss). The output resistance stays at approximately 20 kΩ as the overall or combined magnetic field is increased and then gradually slopes down to the inflection point (approximately 23 Gauss). As the field increases beyond approximately 23 Gauss the resistance tangentially approaches 12 kΩ. The loop gain of the magneto-resistive sensing system 100/200 described in reference to FIGS. 1 and 2 keeps the combined magnetic field constant and is proportional to the slope of the curve in FIG. 3. In a preferred embodiment, the quiescent operating point of the magneto-resistive sensor device should be located in the vicinity of maximum slope. This may help to ensure the highest accuracy. In order to obtain an approximately linear output, an internal bias current is adjusted to place the quiescent operating point of the magneto-resistive sensor device along the quasi-linear portion of the curve in FIG. 3. The external current being measured produces a magnetic field that adds or subtracts from the quiescent magnetic field determined by the bias current. As the quiescent operating point moves left or right along the x axis (i.e. increasing or decreasing the combined magnetic field) the resistance varies as shown in FIG. 3.

Prior art systems have used various sensors to measure current flow. For example, Table 1, below illustrates various prior art sensor technologies and their associated issues/costs.

TABLE 1

| Technology | Profile | Issue | Cost |
|---|---|---|---|
| Hall Effect | Well Established | Low Sensitivity | Medium |
| | Only for Strong Field | | |
| Anisotropic | Sensitivity: 3-5% | Saturation at | High |
| Magnetoresistance | Only for Weak Field | 1 mT | |
| (AMR) | | | |
| Giant | Sensitivity: 13-16% | High Hysteresis | High |
| Magnetoresistance | Only for Weak Field | | |
| (GMR) | | | |
| Current Transformer | N/A | Large Physical | Medium |
| | | Size | |

Various examples of these sensors have been used for detecting current in electrical power distribution plugstrips such as those plugstrips described in U.S. Pat. Nos. 7,043,543, 7,777,365 and 8,305,737, the contents of which are incorporated by reference herein.

Typically, these sensors include toroidal shaped current transformers that step the current down by a factor of several thousand for measurement by an Analog-to-Digital (ND) converter. In some instances, the toroids are “D” shaped, approximately 1″ Wide×1″ Tall×0.5″ Deep for a total volume of approximately 0.5 cubic inches. Newer, smaller current transformers exist that are approximately 0.25 cubic inches. Nonetheless, use of smaller magneto-resistive sensor devices (such as MTJ sensors) to measure magnetic field strength allows electrical power distribution plugstrips to include more densely packed outlets. For example, Crocus Technology makes an integrated circuit MTJ sensor device with a volume of approximately 0.0004 cubic inches that can measure the currents present in the outlets of an electrical power distribution plugstrip. Thus, use of MTJ sensor devices in electrical power distribution plugstrips is attractive from a size perspective as well as from a cost and volume perspective. Furthermore, the techniques described herein to overcome the nonlinearity limitations discussed above (e.g., the nonlinear output resistance attributes of MTJ sensor devices) by maintaining a relatively constant magnetic field at the magneto-resistive sensor device can also be applied to electrical power distribution plugstrips that measure current. The plugstrips described in U.S. Pat. Nos. 7,043,543, 7,777,365 and 8,305,737 utilize at least Hall Effect sensors and/or current transformers to facilitate detection of current. For example, Hall Effect sensors and/or current transformers can be used to measure total current drawn at a power input from the power plug and/or to measure current drawn by individual power outlet sockets of a multiple power outlet electrical power distribution plugstrip. Any one of these sensors and/or current transformers currently included in the electrical power distribution plugstrips can be replaced, in whole or in part, by a magneto-resistive sensor devices (such as MTJ sensors) having a magnetic bias regulator 140/240 described in reference to FIGS. 1 and 2.

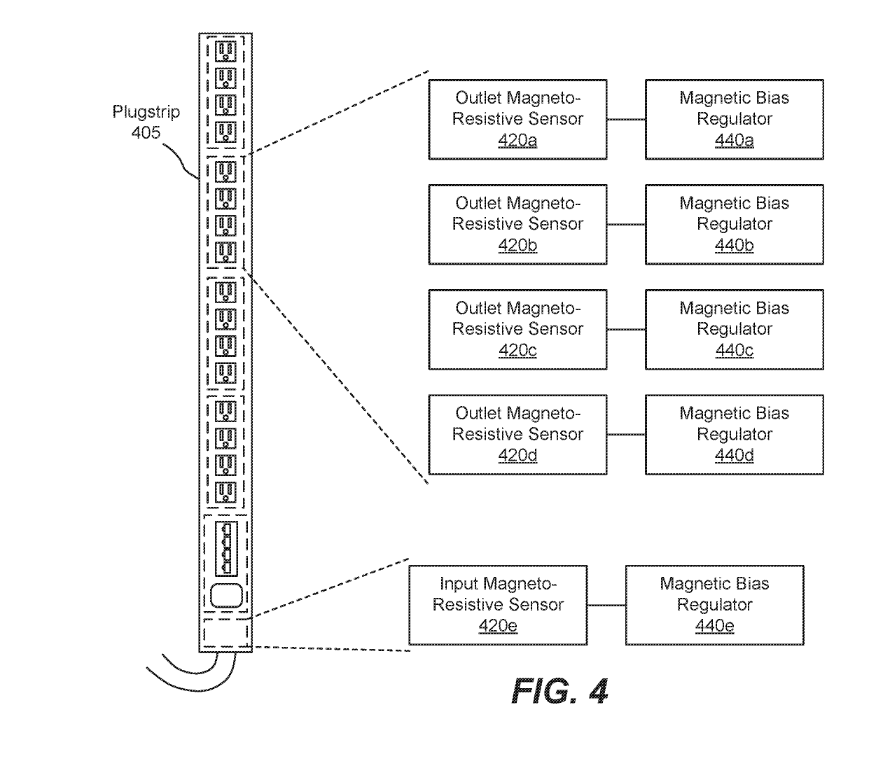

FIG. 4 illustrates an example of an electrical power distribution plugstrip 405, according to an embodiment. The electrical power distribution plugstrip 405 may be connectable to one or more electrical loads in a vertical electrical equipment rack. In some embodiments, the electrical power distribution plugstrip 405 includes a vertical strip enclosure having a thickness and a length longer than a width of the enclosure, a power input penetrating the vertical strip enclosure, multiple power outputs (e.g., power outlets) disposed along a face of the length of the strip enclosure, multiple power control relays disposed within the vertical strip enclosure, a current-related information display disposed on the vertical strip enclosure in current-related information-determining communication with at least one among the power input and power outputs, and a current-related information reporting system associated with the vertical strip enclosure.

Each of the multiple power outputs (e.g., power outlets) are connectable to a an electrical load. The multiple power control relays may be connected to the power input and one or more of the power outputs. The current-related information display may be in current determining communication with one or more of the power outputs through at least one current sensing device. The current sensing device may include the magneto-resistive sensor device and a magnetic bias regulator described herein. The current-related information reporting system may be in current-related information-determining communication with the power input and/or one or more of the power outputs. The current-related information reporting system may also be connectable in current-related information transfer communication with a separate communications network distal from the electrical power distribution plugstrip 405.

Outlet magneto-resistive sensor devices (such as outlet magneto-resistive sensors 420a-420d) may be associated with each power output of the plugstrip 405. The outlet magneto-resistive sensor devices may sense the current at each associated power output. Magnetic bias regulators 440a-440d correspond to each of the outlet magneto-resistive sensor devices 420a-420d and may help the sensor devices 420a-420d maintain approximately linear operation, as further described above. While FIG. 4 shows four outlet magnetic-resistive sensor devices 420a-420d and four magnetic bias regulators 440a-440d, it should be understood that the plugstrip 405 may include additional magneto-resistive sensor devices and magnetic bias regulators corresponding to other power outputs. Furthermore, while shown in a one-to-one correspondence with the power outputs of the plugstrip 405, it should be understood that magneto-resistive sensor devices and magnetic bias regulators may correspond to groups of power outputs.

An input magneto-resistive sensor device 420e may be associated with the power input of the plugstrip 405. The input magneto-resistive sensor device 420e may sense the current associated with the power input of the plugstrip 405. A magnetic bias regulator 440e corresponds to the input magneto-resistive sensor device 420e and helps the sensor device 420e maintain approximately linear operation, as further described above. While FIG. 4 shows one input magnetic-resistive sensor device 420e and magnetic bias regulator 440e associated with the power input, it should be understood that the plugstrip 405 may include additional magneto-resistive sensor devices and magnetic bias regulators corresponding to additional power inputs, such as power inputs corresponding to multiple phases.

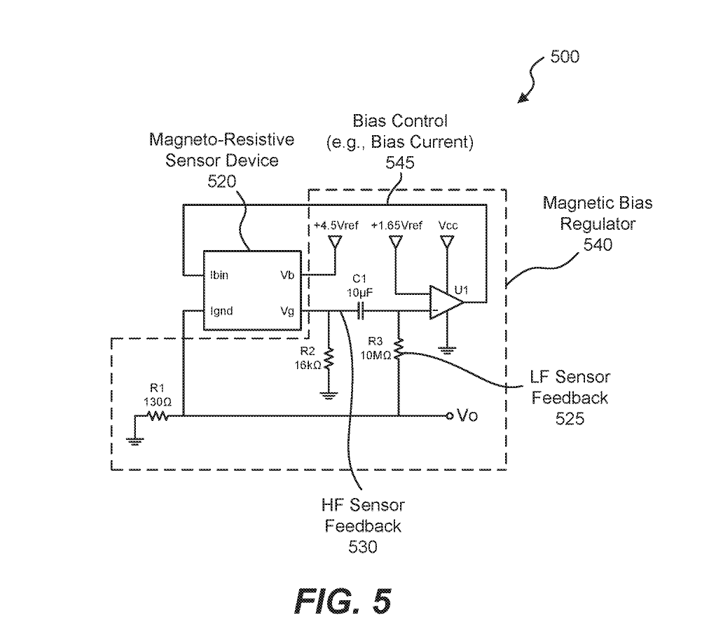

FIG. 5 is a schematic electrical diagram showing another example of a magneto-resistive sensing system 500, according to an embodiment. The system 500 differs from the system 200 described in reference to FIG. 2 in that it contains a single op amp U1 to derive a bias control 545 (e.g., bias current) that is proportional to the current sensed by the magneto-resistive sensing device 520. The bias control 545 output by the op amp U1 is centered at approximately half of the full scale input of an analog-to-digital convertor receiving the sensor output Vo. For example, the op amp U1 may be centered at 1.65 VDC, as shown in FIG. 5.

A low frequency (LF) sensor feedback loop 525 adjusts the average bias current associated with the bias control 545 in response to the operation of the magneto-resistive sensor device 520. The average bias current positions the fixed operating point of the magneto-resistive sensor device 520 within the quasi-linear region of the sensor's output resistance curve under the condition of a zero external magnetic field. A high frequency (HF) sensor feedback loop 530 varies the AC component of the bias control 545 to substantially cancel the externally applied magnetic field from the current carrying conductor.

The technology described herein overcomes the nonlinearity limitations discussed above (e.g., the nonlinear output resistance attributes of MTJ sensor devices) by keeping the magnetic field at the magneto-resistive sensor device 520 constant. The magnetic field is kept constant by varying an internal magnetic field so that the field at the magneto-resistive sensor device 520 remains constant. In this manner, the magneto-resistive sensor device 520 may operate at various bias points on the curve shown in FIG. 3, so long as the bias point remains constant. Variations in the resistance of the magneto-resistive sensor device 520 due to temperature, or variations in resistance due to product variation which would cause non-linearity errors in a typical sensing circuit are mitigated by the feedback loops 525 and 530. The system 500 shown in FIG. 5 further offers cost and space advantages and is highly accurate due to the high gain in the high frequency sensor feedback loop 530.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof, means any connection or coupling, either direct or indirect, between two or more elements; the coupling of connection between the elements can be physical, logical, or a combination thereof. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or,” in reference to a list of two or more items, covers all of the following interpretations of the word: any of the items in the list, all of the items in the list, and any combination of the items in the list.

The above detailed description of embodiments of the disclosure is not intended to be exhaustive or to limit the teachings to the precise form disclosed above. While specific embodiments of, and examples for, the disclosure are described above for illustrative purposes, various equivalent modifications are possible within the scope of the disclosure, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified to provide alternative or sub-combinations. Each of these processes or blocks may be implemented in a variety of different ways. Also, while processes or blocks are, at times, shown as being performed in a series, these processes or blocks may instead be performed in parallel, or may be performed at different times. Further, any specific numbers noted herein are only examples: alternative implementations may employ differing values or ranges.

The teachings of the disclosure provided herein can be applied to other systems, not necessarily the system described above. The elements and acts of the various embodiments described above can be combined to provide further embodiments.

Any patents and applications and other references noted above, including any that may be listed in accompanying filing papers, are incorporated herein by reference. Aspects of the disclosure can be modified, if necessary, to employ the systems, functions, and concepts of the various references described above to provide yet further embodiments of the disclosure.

These and other changes can be made to the disclosure in light of the above Detailed Description. While the above description describes certain embodiments of the disclosure, and describes the best mode contemplated, no matter how detailed the above appears in text, the teachings can be practiced in many ways. Details of the system may vary considerably in its implementation details, while still being encompassed by the subject matter disclosed herein. As noted above, particular terminology used when describing certain features or aspects of the disclosure should not be taken to imply that the terminology is being redefined herein to be restricted to any specific characteristics, features, or aspects of the disclosure with which that terminology is associated. In general, the terms used in the following claims should not be construed to limit the disclosure to the specific embodiments disclosed in the specification, unless the above Detailed Description section explicitly defines such terms. Accordingly, the actual scope of the disclosure encompasses not only the disclosed embodiments, but also all equivalent ways of practicing or implementing the disclosure under the claims.

While certain aspects of the disclosure are presented below in certain claim forms, the inventors contemplate the various aspects of the disclosure in any number of claim forms. For example, while only one aspect of the disclosure is recited as a means-plus-function claim under 35 U.S.C. §112, ¶6, other aspects may likewise be embodied as a means-plus-function claim, or in other forms, such as being embodied in a computer-readable medium. (Any claims intended to be treated under 35 U.S.C. §112, ¶6 will begin with the words “means for.”) Accordingly, the applicant reserves the right to add additional claims after filing the application to pursue such additional claim forms for other aspects of the disclosure.

The detailed description provided herein may be applied to other systems, not necessarily only the system described above. The elements and acts of the various examples described above can be combined to provide further implementations of the present technology. Some alternative implementations may include not only additional elements to those implementations noted above, but also may include fewer elements. These and other changes can be made to the present technology in light of the above Detailed Description. While the above description defines certain examples, and describes the best mode contemplated, no matter how detailed the above appears in text, the present technology can be practiced in many ways. Details of the system may vary considerably in its specific implementation, while still being encompassed by the technology disclosed herein. As noted above, particular terminology used when describing certain features or aspects should not be taken to imply that the terminology is being redefined herein to be restricted to any specific characteristics, features, or aspects with which that terminology is associated. In general, the terms used in the following claims should not be construed to limit the present technology to the specific examples disclosed in the specification, unless the above Detailed Description section explicitly defines such terms. Accordingly, the actual scope of the present technology encompasses not only the disclosed examples, but also all equivalent ways of practicing or implementing the technology.

I/We claim:

1. A current sensing circuit comprising:
a magneto-resistive sensor device proximate to a current carrying conductor and configured to output a voltage representative of a current carried by the proximate current carrying conductor; and
a first sensor feedback loop responsive to an alternating magnetic field generated by the current carried by the current carrying conductor, the first sensor feedback loop being configured to supply a bias current to the magneto-resistive sensor device, and substantially cancel the alternating magnetic field generated by the current carried by the current carrying conductor.

2. The current sensing circuit of claim 1, further comprising:
a second sensor feedback loop configured to adjust an average level of the bias current.

3. The current sensing circuit of claim 1, wherein the first sensor feedback loop comprises an operational amplifier in electrical communication with the magneto-resistive sensor device.

4. The current sensing circuit of claim 1, further comprising:
an analog-to-digital converter configured to sample the output of the magneto-resistive sensor device.

5. The current sensing circuit of claim 4, wherein a center level of the bias current is based at least in part on a full scale input level of the analog-to-digital convertor.

6. The current sensing circuit of claim 1, wherein the current carrying conductor is a power output component of an electronic power distribution plugstrip.

7. The current sensing circuit of claim 1, wherein the current carrying conductor is a power input component of an electronic power distribution plugstrip.

8. A current sensing system comprising:
a current carrying conductor;
a magneto-resistive sensor device proximate to the current carrying conductor and configured to:
determine a magnetic field strength in the vicinity of the magneto-resistive sensor device, wherein the magnetic field strength comprises an external alternating magnetic field component occurring as a result of a current carried by the current carrying conductor and an internal magnetic field component occurring as a result of an internal magnetic bias of the magneto-resistive sensor device; and
convert the magnetic field strength to a voltage representative of the current carried by the current carrying conductor; and
a magnetic bias regulator configured to:
detect resistance information associated with the magneto-resistive sensor device; and
modify the internal magnetic bias of the magneto-resistive sensor device based at least in part on the resistance information.

9. The current sensing system of claim 8, further comprising:
an analog-to-digital converter configured to sample the voltage representative of the current in the current carrying conductor.

10. The current sensing system of claim 8, wherein the current carrying conductor is a power output component of an electronic power distribution plugstrip.

11. The current sensing system of claim 8, wherein the current carrying conductor is a power input component of an electronic power distribution plugstrip.

12. The current sensing system of claim 8, further comprising:
a current-related information display in current determining communication with the magneto-resistive sensor device.

13. A method comprising:
monitoring a magneto-resistive sensor device for sensor feedback; and
generating a bias control signal based on the sensor feedback,
wherein the bias control signal substantially cancels an externally applied alternating magnetic field from a current carrying conductor.

14. An electrical power distribution plugstrip connectable to one or more electrical loads in a vertical electrical equipment rack, the electrical power distribution plugstrip comprising:
A. a vertical strip enclosure having a thickness and a length longer than a width of the enclosure;
B. a power input penetrating said vertical strip enclosure;
C. a plurality of power outputs disposed along a face of said length of the strip enclosure, each among the plurality of power outputs being connectable to a corresponding one of said one or more electrical loads;
D. a plurality of power control relays disposed in said vertical strip enclosure, each among said plurality of power control relays being connected to said power input and one or more of said plurality of power outputs;
E. a current-related information display disposed on said vertical strip enclosure in current-related information-determining communication with at least one among said power input and said plurality of power outputs,
wherein the current-related information display is in current determining communication with all among the plurality of power outputs through at least one current sensing device, the current sensing device comprising a magneto-resistive sensor device and a magnetic bias regulator; and
F. a current-related information reporting system associated with said vertical strip enclosure and being (i) in current-related information-determining communication with at least one among said power input and said plurality of power outputs, and (ii) connectable in current-related information transfer communication with a separate communications network distal from the electrical power distribution plugstrip.
